(19) United States
(12) Patent Application Publication
(10) Pub. No.: US 2007/0102039 A1
(43) Pub. Date: May 10, 2007

(54) Electrolyte composition for dye-sensitized solar cell, manufacturing method of the composition, and dye-sensitized solar cell including the composition

(76) Inventors: Kwang Man Kim, Daejeon-city (KR); Man Gu Kang, Daejeon-city (KR); Nam Gyu Park, Daejeon-city (KR); Kwang-Sun Ryu, Daejeon-city (KR); Soon Ho Chang, Daejeon-city (KR)

Correspondence Address: LADAS & PARRY LLP, 224 SOUTH MICHIGAN AVENUE, SUITE 1600, CHICAGO, IL, 60604, US

(21) Appl. No.: 11/544,143

(22) Filed: Oct. 6, 2006

(30) Foreign Application Priority Data
Nov. 7, 2005 (KR) 10-2005-0106034

(51) Int. Cl. H01L 31/00

(52) U.S. Cl. 136/263

(57) ABSTRACT

Provided are an electrolyte composition of a dye-sensitized solar cell, a manufacturing method thereof, and a dye-sensitized solar cell comprising the composition. The composition comprises a polyvinylidene fluoride (PVDF) based high polymer and titanium dioxide nanoparticles serving as an inorganic material based filler. Using the PVDF based high polymer in the composition can solidify the composition, and this solidification can contribute to the flexibility of a solar cell. Also, the inorganic material based filler, i.e., the titanium dioxide nanoparticles, can reinforce the collection and retention of an aqueous component comprising iodide ions, which are carriers within the electrolyte. Accordingly, compared to typical high polymer based electrolyte solutions, excellent photoelectric conversion efficiency can be achieved with the above electrolyte composition.

### CROSS-REFERENCE TO RELATED PATENT APPLICATION

This application claims the benefit of Korean Patent Application No. 10-2005-0106034, filed on Nov. 7, 2005, in the Korean Intellectual Property Office, the disclosure of which is incorporated herein in its entirety by reference.

### BACKGROUND OF THE INVENTION

1. Field of the Invention

The present invention relates to an electrolyte composition of a dye-sensitized solar cell, and more particularly, to an electrolyte including polyvinylidene fluoride (PVDF) based high polymers and titanium dioxide (TiO₂) nanoparticles.

2. Description of the Related Art

As fossil fuel sources become depleted and then expensive, many attempts have been made to use solar energy as a substitute. The public is becoming increasingly aware of environmental pollution-related problems, and thus, many political regulations such as the Kyoto protocol that limit the generation of carbon dioxide are being arranged. Solar energy technology that can generate electricity with minimal environmental pollution may be an important solution to the problems of environmental pollution that occur through the use of non-renewable energy resources.

Dye-sensitized solar cell is a photoelectrochemical solar cell that was invented by Michael Gratzel et al. in 1991. Since dye-sensitized solar cells are less expensive than other solar cells and have an energy conversion efficiency of about 11%, they are expected to be a next-generation solar cell that will replace typical silicon solar cells. Typically, dye-sensitized solar cells include a photo-electrode, an iodine-based electrolyte, and an opposite electrode. The photo-electrode includes TiO₂-containing porous oxide nanoparticles on which photosensitive dye molecules are adsorbed. Dye-sensitized solar cells can be manufactured at lower costs than typical silicon solar cells. However, in an iodine-based electrolyte used as an electrolyte in a dye-sensitized solar cell, iodide ions for oxidation and reduction reactions are dissolved in an organic solvent. The solvent of the electrolyte is likely to become volatile when an external temperature increases due to solar light radiated onto the solar cells. Since the electrolyte exists in a liquid state, it may be difficult to achieve flexible dye-sensitized solar cells, wherein the dye-sensitized solar cells have a wide range of applications as a next generation energy resource.

As described in U.S. Pat. No. 6,756,537 entitled “Dye-Sensitized Solar Cells Including Polymer Electrolyte Gel Containing Poly(vinylidene fluoride),” in the name of M. Kang et al., dye-sensitized solar cells using a polyvinylidene fluoride based copolymer as a high polymer matrix and including a gel type high polymer electrolyte using an N-methyl-2-pyrrolidone (NMP) solvent are presented. The maximum photoelectric conversion efficiency of such dye-sensitized solar cells is about 2.9%. Therefore, a high polymer electrolyte composition that includes a polyvinylidene fluoride based copolymer and provides high photoelectric conversion efficiency to dye-sensitized solar cells needs to be developed.

### SUMMARY OF THE INVENTION

The present invention provides an electrolyte composition for dye-sensitized solar cells that allows for better durability and flexibility in solar cells, which are usually degraded when a volatile solvent is used.

The present invention also provides a method of manufacturing an electrolyte composition for dye-sensitized solar cells that allows for better durability and flexibility in solar cells, which are usually degraded when a volatile solvent is used.

The present invention also provides a dye-sensitized solar cell with excellent energy conversion efficiency using an electrolyte of a dye-sensitized solar cell that allows for better durability and flexibility in solar cells, which are usually degraded when a volatile solvent is used.

According to an aspect of the present invention, there is provided an electrolyte composition of a dye-sensitized solar cell, the composition including: N-methyl-2-pyrrolidone; a copolymer of vinylidene fluoride and hexafluoropropylene; and titanium dioxide nanoparticles.

The amount of the copolymer may be approximately 5 to 20 wt % of the N-methyl-2-pyrrolidone, which acts as a solvent, and the amount of the TiO₂ nanoparticles may be 10 to 30 wt % of the mixture of the copolymer. The TiO₂ nanoparticles Iodine (I₂) and an iodine compound can be dissolved in the resultant solution to maintain a certain molar concentration with respect to the solvent. The iodine and the iodine compound provide carrier ion pairs (I₃⁻/I⁻), which stimulate an oxidation and reduction reaction.

According to another aspect of the present invention, there is provided a method of manufacturing an electrolyte composition of a dye-sensitized solar cell, the method including: adding a copolymer of vinylidene fluoride and hexafluoropropylene and titanium dioxide nanoparticles to an N-methyl-2-pyrrolidone solvent; adding titanium dioxide nanoparticles to the copolymer dissolved in the solvent; and adding iodine and an iodine compound, both providing oxidizing and reducing ions, to the solution comprising the titanium dioxide nanoparticles, the copolymer and the solvent.

According to another aspect of the present invention, there is provided a dye-sensitized solar cell including: a semiconductor electrode obtained by coating nanoparticles of an oxide material on a conductive substrate; an opposite electrode; and an electrolyte composition interposed between the semiconductor electrode and the opposite electrode, the electrolyte composition comprising N-methyl-2-pyrrolidone, a copolymer of vinylidene fluoride and hexafluoropropylene, and titanium dioxide nanoparticles.

Particularly, the semiconductor electrode may be manufactured by coating TiO₂ nanoparticles having a crystalline diameter of approximately 5 to 30 nm on a transparent conductive glass substrate overlaid with indium tin oxide (ITO) or tin dioxide (SnO₂). Dye molecules such as ruthenium (Ru) based adhesive agents are chemically adsorbed onto the surface of the TiO₂ nanoparticles.

The opposite electrode may be obtained by coating a platinum (Pt) layer on one surface of a transparent conducive glass substrate overlaid with ITO or SnO₂. The Pt layer of the opposite electrode faces the semiconductor electrode.

A method of manufacturing elements of the dye-sensitized solar cell such as a semiconductor electrode comprising the TiO₂ nanoparticles and an opposite electrode is taught in U.S. Pat. No. 6,756,537, entitled “Dye-Sensitized Solar Cells Including Polymer Electrolyte Gel Contaning Poly (Vinylidene Fluoride)” in the name of M. Kang et al.

The TiO₂ nanoparticles of the composition can provide better collection and retention of the solvent than a polymer electrolyte solution of a conventional dye-sensitized solar cell. Hence, the volatility of the solvent can be reduced and the dye-sensitized solar cell can have long-term stability. Also, photoelectric conversion efficiency can be improved.

### BRIEF DESCRIPTION OF THE DRAWINGS

The above and other features and advantages of the present invention will become more apparent by describing in detail exemplary embodiments thereof with reference to the attached drawings in which:

FIG. 1 is a graph illustrating current-voltage characteristics of the dye-sensitized solar cells of Examples 1 through 4 and Comparative Examples 1 and 3.

### DETAILED DESCRIPTION OF THE INVENTION

The present invention will now be described more fully with reference to the accompanying drawings, in which an electrolyte composition of a dye-sensitized solar cell and a dye-sensitized solar cell comprising the same according to exemplary embodiments of the invention are shown. Exemplary test results for electrical characteristics of the dye-sensitized solar cell will be described. The invention may, however, be embodied in many different forms and should not be construed as being limited to the embodiments and exemplary test results set forth herein; rather, these embodiments are provided so that this disclosure will be thorough and complete, and will fully convey the concept of the invention to those skilled in the art.

### EXAMPLE 1

N-methyl-2-pyrrolidone (NMP) and a copolymer of vinylidene fluoride (PVDF) and hexafluoropropylene (HFP) were mixed at a weight ratio of approximately 85:15 to obtain a uniform transparent solution. Here, the NMP is a solvent provided by Aldrich, and the prepared copolymer is KynarFlex 2801, manufactured by Atofina Chemicals, and comprises approximately 12 mol % of HFP. 10 wt % of titanium dioxide (TiO₂) nanoparticles, based on the amount of the transparent solution of PVDF-HFP and TiO₂, were added to the transparent solution. The titanium dioxide (TiO₂) nanoparticles were provided by PC-101, were commercially prepared by Japan Titan Kogyo and had anatase crystalline characteristics with an average crystalline diameter of approximately 20 nm. The resultant solution, which includes the TiO₂ nanoparticles, the solvent and the copolymer, was then mechanically stirred. At this time, ultrasonic waves might be applied until the solution was uniformly distributed. To provide oxidizing and reducing ions, a predetermined amount of 1-hexyl-2,3-dimethyl imidazolium iodide (C₆DMI) that makes the concentration of approximately one molar solution (1M) with respect to the weight of the solvent was added to the resultant solution. Also, using substantially the same stoichiometry for the C₆DMI, approximately 0.1 M iodine (I₂) was added to the resultant solution and stirred to obtain a uniformly distributed electrolyte. The resultant slurry obtained after stirring the mixture had a viscosity of approximately 35,000 cPoise (cP) to approximately 40,000 cP, since the TiO₂ nanoparticles of the composition can provide better collection and retention of the solvent than a polymer electrolyte solution of a conventional dye-sensitized solar cell. The slurry was then coated to a thickness of approximately 10 micrometers over a photo-electrode formed of TiO₂ nanoparticles, and an opposite electrode was placed over the resultant photo-electrode.

Other processes for fabricating the dye-sensitized solar cell and a method of measuring the photoelectric conversion efficiency of the dye-sensitized solar cell were substantially the same as described in U.S. Pat. No. 6,756,537, and thus, the details thereof will not be described herein.

### EXAMPLE 2

A dye-sensitized solar cell was manufactured in the same way as the dye-sensitized solar cell of Example 1 except that approximately 1 M lithium iodide (LiI) and approximately 0.1 M iodine (I₂) were used as compounds for supplying oxidizing and reducing ions.

### EXAMPLE 3

A dye-sensitized solar cell was manufactured in the same manner as the dye-sensitized solar cell of Example 1 except that 30 wt % of the TiO₂ nanoparticles based on the amount of the transparent solution of PVDF-HFP and TiO₂, were added to the transparent solution.

### EXAMPLE 4

A dye-sensitized solar cell was manufactured in the same manner as the dye-sensitized solar cell of Example 3 except that approximately 1 M LiI and approximately 0.1 M iodine (I₂) were used as compound for supplying oxidizing and reducing ions.

### COMPARATIVE EXAMPLES 1 AND 2

Dye-sensitized solar cells were prepared by performing substantially the same processes as Examples 1 and 2 except that TiO₂ nanoparticles were not added.

For the evaluation of the electrical characteristics of the dye-sensitized solar cells, the dye-sensitized solar cells of Example 1 through 4 were used as a test group, and the dye-sensitized solar cells of Comparative Examples 1 and 2 were used as a comparison group.

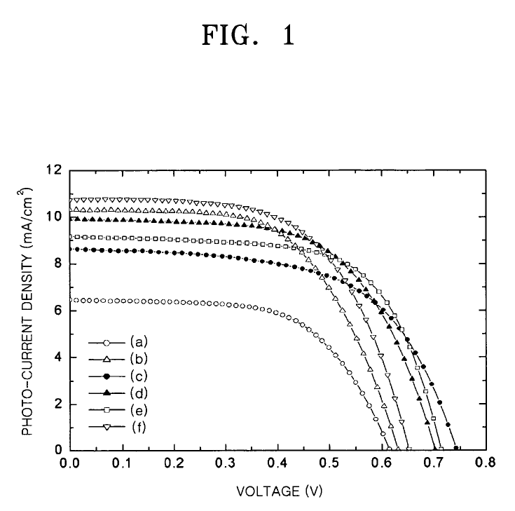

FIG. 1 is a graph illustrating current-voltage characteristics of the dye-sensitized solar cells of Examples 1 through 4 and Comparative Examples 1 and 3. In FIG. 1, (a) and (b) represent Comparative Examples 1 and 2, respectively, and (c) through (f) represent Examples 1 through 4, respectively.

Referring to FIG. 1, the dye-sensitized solar cell of Example 1 in which 1-hexyl-2,3-dimethyl imidazolium iodide was used and TiO₂ nanoparticles were added thereto had better electrical characteristics than the dye-sensitized cell of Comparative Example 1 in which 1-hexyl-2,3-dimethyl imidazolium iodide was used but TiO₂ nanoparticles were not added. Comparing the dye-sensitized solar cells of Examples 1 and 3, it was found that the electrical characteristics improved as the quantity of the TiO₂ nanoparticles added was increased. In addition, comparing the dye-sensitized solar cell of Comparative Example 2 in which LiI was used as an iodine compound and TiO₂ nanoparticles were not used with the dye-sensitized solar cells of Example 2 and 4 in which LiI was used as an iodine compound and TiO₂ nanoparticles were used, the electrical characteristics were best in the dye-sensitized solar cell of Example 2 including approximately 10 wt % of the TiO₂ nanoparticles, followed by the dye-sensitized solar cell of Comparison Example 2 including no TiO₂ nanoparticles and then the dye-sensitized solar cell of Example 4 including approximately 30 wt % of the TiO₂ nanoparticles.

Referring to Table 1 below, the use of TiO₂ nanoparticles improved an opening circuit voltage, a short circuit current and a fill factor. Particularly, when the TiO₂ nanoparticles were added, the photoelectric conversion efficiency, which is an important factor of solar cells, was much better than when no TiO₂ nanoparticles were used. When approximately 30 wt % of the TiO₂ nanoparticles based on the transparent solution were added to the transparent solution, the photoelectric conversion efficiency of those Example and Comparative Example groups using 1-hexyl-2,3 dimethyl imidazolium iodide was improved from approximately 2.42% when no TiO₂ particles were used to approximately 4.26%. In those groups using LiI, the use of approximately 10 wt % of the TiO₂ nanoparticles improved the photoelectric conversion efficiency from approximately 3.81% when no TiO₂ particles were used to approximately 4.25%.

TABLE 1

| | Content of Composition within Electrolyte | | | Density of Short | | Conversion |
|---|---|---|---|---|---|---|
| | TiO₂ nano- | Compound Providing | Open Circuit | Circuit Current | Fill | Efficiency |
| | particles (wt %) | Iodide Ion pairs | Voltage (V) | (mAcm⁻²) | Factor | (%) |
| Embodiment 1 | 10 | 1M C₆DMI/0.1M I₂ | 0.743 | 8.63 | 0.595 | 3.82 |
| Embodiment 2 | 10 | 1M LiI/0.1M I₂ | 0.702 | 9.91 | 0.611 | 4.25 |
| Embodiment 3 | 30 | 1M C₆DMI/0.1M I₂ | 0.714 | 9.15 | 0.652 | 4.26 |
| Embodiment 4 | 30 | 1M LiI/0.1M I₂ | 0.653 | 10.73 | 0.600 | 4.20 |
| Comparitive Example 1 | 0 | 1M C₆DMI/0.1M I₂ | 0.615 | 6.46 | 0.609 | 2.42 |
| Comparitive Example 2 | 0 | 1M LiI/0.1M I₂ | 0.631 | 10.31 | 0.585 | 3.81 |

According to exemplary embodiments of the present invention, the electrolyte containing high polymers with TiO₂ nanoparticles for use in dye-sensitized solar cells can provide long-term stable photoelectrochemical characteristics by limiting the volatility of a typical organic solvent. Also, the electrolyte according to the exemplary embodiments can have better photoelectric conversion efficiency than dye-sensitized solar cells with a typical high polymer containing electrolyte. Since an electrolyte system can be solidified, a flexible energy source can be achieved.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An electrolyte composition of a dye-sensitized solar cell, the composition comprising:
N-methyl-2-pyrrolidone;
a copolymer of vinylidene fluoride and hexafluoropropylene; and
titanium dioxide nanoparticles.

2. The composition of claim 1, wherein the electrolyte composition comprises 5-20 wt % of the copolymer bases on N-methyl-2-pyrrolidone, and the electrolyte composition comprises 10-30 wt % of the titanium dioxide nanoparticles based on the copolymer.

3. The composition of claim 1, having a viscosity of approximately 35,000 cP to approximately 40,000 cP.

4. The composition of claim 1, further comprising iodine and an iodine compound supplying oxidizing and reducing ions.

5. The composition of claim 4, wherein the iodine compound is one of 1-hexyl-2,3-dimethyl imidazolium iodide and lithium iodide.

6. A method of manufacturing an electrolyte composition of a dye-sensitized solar cell, the method comprising:
adding a copolymer of vinylidene fluoride and hexafluoropropylene to an N-methyl-2-pyrrolidone solvent;
adding titanium dioxide nanoparticles to the copolymer dissolved in the solvent; and
adding iodine and an iodine compound, both providing oxidizing and reducing ions, to the solution comprising the titanium dioxide nanoparticles, the copolymer and the solvent.

7. The method of claim 6, wherein the amount of the copolymer added to the solvent is 5 to 20 wt % of the solvent.

8. The method of claim 6, wherein the amount of the titanium dioxide nanoparticles added to the copolymer dissolved in the solvent is approximately 10 to 30 wt % of the copolymer of vinylidene fluoride and hexafluoropropylene.

9. The method of claim 6, wherein the electrolyte composition is manufactured to have a viscosity of approximately 35,000 cP to approximately 40,000 cP.

10. A dye-sensitized solar cell comprising:
a semiconductor electrode obtained by coating nanoparticles of an oxide material on a conductive substrate;
an opposite electrode; and
an electrolyte composition interposed between the semiconductor electrode and the opposite electrode, the electrolyte composition comprising N-methyl-2-pyrrolidone, a copolymer of vinylidene fluoride and hexafluoropropylene, and titanium dioxide nanoparticles.

11. The dye-sensitized solar cell of claim 10, wherein the N-methyl-2-pyrrolidone, the copolymer and the titanium dioxide nanoparticles are mixed with a weight ratio of approximately 1:5-20:10-30.

12. The dye-sensitized solar cell of claim 10, wherein the electrolyte composition has a viscosity of approximately 35,000 cP to approximately 40,000 cP.

13. The dye-sensitized solar cell of claim 10, further comprising iodine and an iodine compound supplying oxidizing and reducing ions.

14. The dye-sensitized solar cell of claim 13, wherein the iodine compound is one of 1-hexyl-2,3-dimethyl imidazolium iodide and lithium iodide.
